(19) United States
(12) Patent Application Publication
(10) Pub. No.: US 2007/0273276 A1
(43) Pub. Date: Nov. 29, 2007

(54) Process for Producing Organic Light-Emitting Devices

(76) Inventors: Clemens Ottermann, Hattersheim (DE); Georg Sparschuh, Aspisheim (DE)

Correspondence Address: OHLANDT, GREELEY, RUGGIERO & PERLE, LLP, ONE LANDMARK SQUARE, 10TH FLOOR, STAMFORD, CT, 06901, US

(21) Appl. No.: 10/556,752

(22) PCT Filed: May 24, 2004
(86) PCT No.: PCT/EP04/05601

§ 371 Date: Dec. 8, 2006

(30) Foreign Application Priority Data
May 30, 2003 (DE) 10324880.3

(51) Int. Cl. H01J 1/66; H01L 51/56

(52) U.S. Cl. 313/505; 438/34; 257/E51.019; 257/E21.464

(57) ABSTRACT

A process for producing light-emitting devices, particularly OLEDs, which saves material and produces a homogeneous light-emitting layer, is provided. The process involves applying layers to a substrate so as to produce a layer assembly, including the steps of 1) applying an electrode, 2) producing a surface with depressions, and 3) applying organic light-emitting material that is introduced into the depressions.

### CROSS REFERENCE TO RELATED APPLICATIONS

Pursuant to 35 U.S.C. §365, this application claims the benefit of International Application No. PCT/EP2004/005601, filed May 30, 2003, the entire contents of which are incorporated by reference herein.

### BACKGROUND OF THE INVENTION

1. Field of the Invention

The invention relates to a process for producing an OLED in general and by applying layers to a substrate to produce a layer assembly in particular, and to the OLED itself.

2. Description of Related Art

In general, organic light-emitting devices or diodes, better known as OLEDs, are built up from a layer assembly or a layer structure comprising an organic electroluminescent layer between two electrode layers, which is applied to a suitable substrate. In this arrangement, in each case one of the electrode layers acts as a cathode and the other acts as an anode.

OLEDs are distinguished by particular advantages over other luminous means. For example, OLEDs have very promising properties for flat screens, since they allow a considerably wider viewing angle than LCD or liquid crystal displays and, as self-illuminating displays, also allow reduced consumption of power compared to the back-lit LCD displays. Moreover, OLEDs can be produced as thin, flexible films which are particularly suitable for specific applications in lighting and display technology.

However, OLEDs are not just suitable for pixelated displays. They can in general terms be used as luminous means for a very wide range of applications, for example for self-illuminating signs and information boards.

One of the main cost factors involved in the production of OLEDs is the material costs of the organic luminous medium and of the transparent-conductive substrates. It is known to use TCO (transparent conductive oxide) coatings of glass or polymer substrates, typically ITO (indium tin oxide) or SnO₂ (tin oxide). To achieve homogeneous luminous density distributions, particularly large-area OLED applications require high-quality TCO layers with low sheet resistances. These substrates are very expensive, or else the best coatings currently available are as yet inadequate for some OLED applications. One technical solution is to improve the conductivity of the transparent layers by coating them with metallic line structures (known as busbars), which are responsible for current conduction. The TCO or other inorganic or organic conductive-transparent coatings, such as for example thin metal layers or PEDOT or PANI (polyaniline), then serve only to locally distribute the currents over the surface.

Therefore, for cost-effective production, material-saving coating processes are required for the electroluminescent material. Substrates which are compatible with the coating process, ideally have a good transparency (>80%) and a sufficiently high mean surface conductivity but do not require high-quality and expensive TCO coatings for this purpose should also be used.

In principal, materials used to produce organic layers for OLED applications are divided into two classes of materials depending on the way in which they are deposited:
“Small molecules (SM)”, i.e. organic molecules with molecular weights of <1000 amu (a conventional representative of this class is Alq₃), which can be thermally vaporized without decomposing and sublime from the vapor phase onto the substrates (vacuum evaporation coating or plasma vapor deposition processes, PVD). The deposited layers are patterned (for example for pixelated color displays) by means of conventional PVD techniques, such as shadow masks.
“Light-emitting polymers (LEP)”, in particular organic molecules with molecular weights of approx. 1 000 000 amu and more (conventional representatives include PPV and perylene), decompose under relatively high thermal loads before they are vaporized. LEPs are dissolved and deposited using conventional liquid coating processes, such as for example spin coating, dip coating or blade coating. However, these processes do not save coating material (and are therefore expensive), and consequently the layer which is to be deposited cannot be patterned or can only be patterned at relatively high cost. Other approaches use printing processes (screen printing or intaglio printing) or inkjet techniques to apply the layers in patterned form using less material.

Approaches involving the liquid deposition of SM materials are likewise known, but have not to date given satisfactory results.

One focus of OLED technology is the small-area display sector (mobile phones, PDAs), i.e. precision-patterned coatings. The deposition technologies for these applications have been correspondingly sought out and optimized. These coating processes are of only limited suitability for large-area homogeneous or only imprecisely patterned illumination applications.

The PVD processes and also coating from the liquid phase are in principle suitable for uniform large-area coating. However, in this case too, coating processes which save as much material as possible are preferable for cost reasons, which means that conventional PVD processes are generally ruled out. Both screen printing and inkjet techniques (JP 05251186 A1, JP 10012377 A1) for coating with LEPs have potential in the illumination sector. A vapor coating process (WO 0161071 A2) has potential for SM-OLEDs.

Screen-printing processes for coating the LEP are not yet technically developed enough for commercial applications. Inkjet techniques are likewise still being tested, although they are at a more advanced stage than screen printing.

It is also known to apply passive auxiliary structures composed of insulating photoresist, but this is very complex and therefore makes production more expensive.

### BRIEF SUMMARY OF THE INVENTION

Therefore, the invention is based on the object of providing a process for producing light-emitting devices, in particular OLEDs, which saves material and produces a homogeneous light-emitting layer.

A further object of the invention is to provide a simple and inexpensive process for producing light-emitting devices, in particular OLEDs, which can be used for large areas and on a large industrial scale and constitutes a stable process.

A further object of the invention is to provide a process for producing light-emitting devices, in particular OLEDs, which avoids or at least alleviates the drawbacks of known processes.

The object of the invention is achieved in a surprisingly simple way by the subject matter of the present invention The invention proposes a process for producing an organic light-emitting device or diode, known as an OLED, by applying layers to a substrate or a base, so as to produce a layer assembly.

The substrate is provided, and a first electrically conductive electrode or electrode layer is applied to it, optionally with further layers in between. The first electrode in particular defines an anode.

Furthermore, depressions or recesses are produced on the substrate or one of the layers of the layer assembly, and a layer of an organic light-emitting or electroluminescent material is applied.

The organic electroluminescent material is introduced into the depressions in fluid state, in particular in the liquid state.

In this way, it is advantageously possible to produce a particularly homogeneous electroluminescent layer, which is eminently suitable for use even for large-area applications, in a simple way.

A simple way of producing the surface with depressions is preferably to apply a patterned layer, e.g. a grid structure, the structure of which defines the depressions, so as to form a layer which is patterned in honeycomb form and filled with the electroluminescent material; in this context, the term “in honeycomb form” is not restricted to hexagonal structures. However, structures in honeycomb form composed of hexagons or rectangles are particularly preferred.

It is also preferable for the patterned layer to contain an electrically conductive material or to be electrically conductive. In this embodiment, the patterned and electrically conductive layer defines interconnects for homogenizing the flow of current, which are fundamentally known to the person skilled in the art as busbars.

This reveals a surprising synergistic effect of the invention, namely the double use of the busbars as electrical interconnects and at the same time as a closed frame structure for defining the depressions or recesses to be filled with the electroluminescent material. For this purpose, the busbars are applied to a height which is sufficient to define a sufficiently large cavity.

The light-emitting material is introduced into the depressions in the liquid state, in which respect inkjet processes, blade coating or screen printing are particularly suitable.

The patterned layer or busbars are in electrically conductive contact with the first conductive electrode, in order to perform their function as a current distributor.

In the case of the OLED, the first conductive electrode is in particular a transparent conductive anode layer, for example consisting of ITO, for electrical contact-connection or supply of the electroluminescent layer.

Furthermore, a second conductive electrode or metallic cathode can be applied, in which case the patterned layer and the electroluminescent layer are arranged between the first and second electrodes.

According to a particularly preferred embodiment, the patterned layer and the second conductive electrode are at least directly electrically insulated from one another. This does not mean that they may not be electrically connected to one another in any way, but rather merely means that there is no direct contact between them.

The above mentioned insulation is preferably produced by a patterned insulator layer which is applied to the patterned conductive layer. Conversely, it is also possible for the patterned insulator layer to be applied first, and then for the patterned conductive layer to be applied to it.

The organic light-emitting material used is preferably an electroluminescent polymer, in which case a light-emitting polymer layer interrupted in particular by the patterned conductive layer is formed.

Furthermore, it is preferable for a further polymer layer, more specifically a conductive or hole-conductive polymer layer, to be applied, in particular arranged directly adjacent to the light-emitting polymer layer.

Fundamentally, two orders are proposed for the steps of producing the layer assembly of the OLED to be carried out in:

Order 1

providing the substrate,

then applying the transparent conductive anode, for example consisting of TCO, although if appropriate this step may even be dispensed with,

then applying a conductive patterned layer to produce the depressions,

then applying a conductive polymer layer within the depressions defined by the conductive patterned layer,

then applying a patterned insulator layer to electrically insulate the patterned layer,

then applying a light-emitting polymer layer within the depressions defined by the conductive patterned layer,

then applying a cathode layer, the cathode layer being insulated from direct contact with the conductive patterned layer by means of the patterned insulator layer.

Order 2 (What is Known as an Inverse OLED)

providing the substrate,

then applying a cathode layer, the cathode layer being insulated from direct contact with the conductive patterned layer by means of the patterned insulator layer,

then applying a patterned insulator layer to electrically insulate the cathode layer,

then applying a conductive patterned layer to produce the depressions,

then applying a light-emitting polymer layer within the depressions defined by the conductive patterned layer,

then applying a conductive polymer layer within the depressions defined by the conductive patterned layer,

then applying a transparent conductive electrode over the conductive patterned layer.

### BRIEF DESCRIPTION OF THE DRAWINGS

In the text which follows, the invention is explained in more detail on the basis of exemplary embodiments and with reference to the drawings, in which identical and similar elements are provided with identical reference designations and the features of the various exemplary embodiments can be combined with one another. Furthermore, features which are described in the background of the invention and/or may be known from the prior art are also combined with the invention.

FIG. 1 shows a diagrammatic sectional illustration of conventional layer application by means of inkjet processes,

FIG. 2 shows a diagrammatic sectional illustration of layer application by means of the process according to the invention,

FIG. 3 shows a diagrammatic sectional illustration of busbar amplification on a conductive transparent coating,

FIG. 4 shows a diagrammatic perspective illustration of a patterned grid structure in honeycomb form,

FIG. 5 shows a diagrammatic sectional illustration of an OLED according to the invention,

FIG. 6 shows a diagrammatic sectional illustration of an inverse OLED according to the invention, and

FIGS. 7a-e show diagrammatic sectional illustrations of various process stages involved in producing an OLED in accordance with the invention.

### DETAILED DESCRIPTION OF THE INVENTION

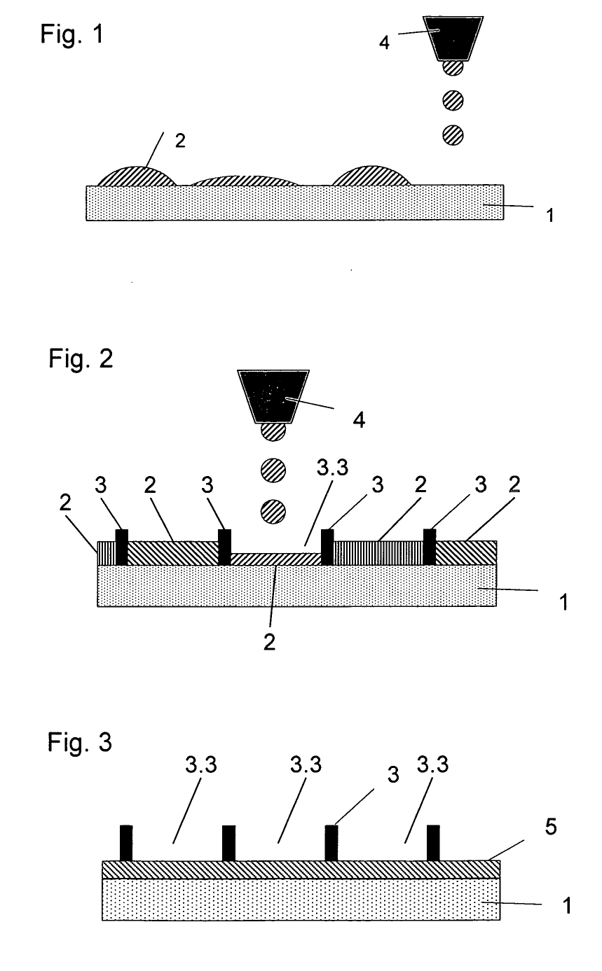

FIG. 1 shows the fundamentally known coating of a substrate glass 1 using a jet nozzle or inkjet spray head 4 with an emerging jet of liquid droplets.

However, the inventors have discovered that the uniform coating of large areas by means of an inkjet process of this type is very technically complex, since very accurate control of the surface properties, in particular the surface energy, and the wetting properties of the substrates to be coated, the coating atmosphere (solvent saturation), ambient temperature (viscosity, drying properties) and the chemical composition of the LEP coating liquid is required over a prolonged period of time (inkjet printing is generally a sequential coating process). Coating defects which typically occur include insufficient flow of the drops 2, which leads to inhomogeneous and inadequate layer formation.

The wetting properties and therefore the formation of the drop shape are critically dependent on the local surface properties of the substrate. Furthermore, in this context the extent to which the drops run across the surface, and the resulting layer thickness with homogeneous coverage, are to a considerable extent linked to one another by the surface properties of the substrate, which makes targeted setting of the layer properties in the process extremely difficult. Process-stable use of this technology on a large industrial scale for the production of OLED luminous products cannot be ensured by means of simple inkjet coating.

FIG. 2 illustrates an inkjet coating according to the invention in a “recess structure” for patterned OLED display applications.

The figure illustrates the substrate glass 1 with a patterned layer 3 comprising webs for forming depressions 3.3 between the webs 3 or for delimiting the pattern. The inkjet spray head 4 introduces electroluminescent OLED polymer liquid in the form of liquid drops into the depressions or recesses 3.3.

The different hatching of the polymer fillings 2 represents different materials, in particular for producing different colors. This further illustrates the huge benefits conferred by the invention, since it is in this way possible to produce multicolor patterned OLEDs in a very simple and accurate way. Therefore, the drawbacks of the process illustrated in FIG. 1 can be elegantly resolved with the aid of the invention when producing highly patterned OLED displays. In this case, for controlled patterning, the inkjet process is used to apply recesses 3.3 to the substrate 1, and these recesses are then filled with the liquid from the inkjet 4. For the sake of simplicity, this figure only illustrates the application of one layer, but this process can also be used or transferred for all the organic layers of an OLED layer sequence. The result is a locally defined coating with a homogeneous layer thickness. The results of coating do not change to a critical extent in the event of slight local differences in the properties of the substrate surface, such as for example the surface energy and therefore the wetting properties of the liquid.

The surface conductivities of conventional TCO coatings (such as ITO or SnO₂ or thin metal layers or organic coatings, such as PEDOT or PANI), with a simultaneous requirement for a high transparency, are inadequate for uniform distribution of current over a large area without significant voltage drops. Therefore, additional metallic interconnects (known as busbars) are used to assist with the conduction of current. These interconnects may also be arranged as a network of lines or a grid on and under the TCO layer and/or along the sides of separate TCO lines.

An embodiment of this type is illustrated in FIG. 3, which represents an outline sketch of busbar amplification on a conductive transparent coating 5. The transparent conductive ITO coating 5 has been applied to the substrate glass 1. In turn, the patterned layer 3 has been applied in the form of metallic busbars to the ITO coating 5.

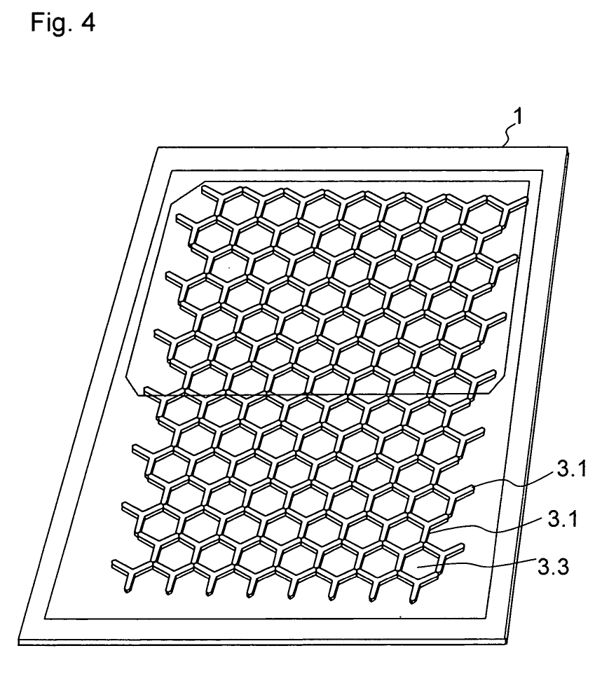

FIG. 4 illustrates an example of a grid structure for the patterned layer 3 or the busbars.

The invention ensures a reduced-cost process for producing large-area homogeneous OLED components. The improvement to the TCO conductivity is achieved by the formation of the busbar structure. This structure is designed in such a way that it can simultaneously be used as an active “recess” structure for the inkjet coating technology. This aspect of the invention, whereby the busbars are simultaneously designed as cavity-forming depressions or recesses, generates a synergistic saving effect.

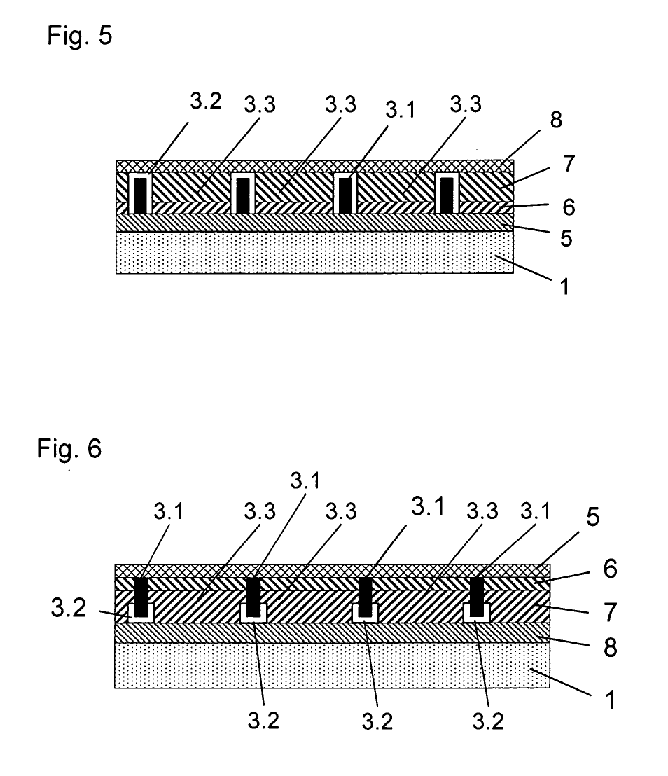

FIG. 5 shows an example of an embodiment of the OLED component design with an inkjet coating of the active recess structure 3.3 of the busbar grid 3.1.

The busbar layer 3.1 for delimiting the structure and distributing current has been formed on the substrate 1. A patterned insulator layer 3.2 has been applied over the busbar structure 3.1. The conductive transparent coating 5 as anode is located between the substrate 1 and the busbar layer 3.1.

A conductive or hole-conductive HTL polymer layer 6 and a directly adjacent light-emitting EL polymer layer 7 are arranged above the anode 5 and between the webs 3.1 or in the depressions 3.3 of the patterned busbar layer. In particular metallic cathode layer 8, which is directly adjacent to the EL polymer layer 7, is arranged right at the top. The HTL polymer layer 6 and an EL polymer layer 7 are directly electrically insulated from the busbars by means of the insulator layer 3.2.

The base used is the transparent substrate 1, e.g. glass, (ultra)thin glass, glass-plastic laminate, polymer-coated (ultra)thin glass or a polymer sheet/film, coated with the conductive (semi)transparent layer or anode layer 5, for example consisting of or containing TCO, in particular ITO, SnO₂, or In₂O₃ or a thin metal layer, an organic thin film of PEDOT, PANI or the like.

The busbar grid structures 3.1 made from metal with a sufficiently high conductivity, e.g. Cr/Cu/Cr layer sequences, including the recess shape or depressions 3.3 with appropriate properties for the inkjet coating process, are deposited thereon. The width and thickness of the structure and the density of the grid mesh openings is additionally adapted to the demands resulting from the boundary conditions for the uniformity of illumination from the EL layer and the current density distribution to be derived therefrom. The surface of the busbars is passivated in order to avoid short circuits in the finished component. This can be done electrochemically or by an additional local coating with an insulator (e.g. metal oxide or metal nitride or polymer).

The active layers of the OLED structure, such as for example the HTL layer 6 (HTL: hole transport layer, e.g. PEDOT or PANI) and the electroluminescence layer 7 (EL layer), e.g. PPV derivatives or polyfluorenes, are introduced into the recesses 3.3 by inkjet means in a routine coating process.

Finally, the cathode 8, which is in particular opaque and/or metallic, e.g. containing Ca/Al or Ba/Al or Mg: Ag, if appropriate also with a thin Li interlayer, or transparent, e.g. of TCO, is applied and the component is encapsulated/passivated.

With this structure, the light which is generated is emitted in particular via the substrate side.

FIG. 6 shows the structure according to the invention of an alternative inverse OLED layer structure with inkjet coating of the active recess structure 3.3 of the busbar grid 3.1. The inverse OLED then radiates out the light in the opposite direction to the substrate 1.

Since the conductivity of the transparent anode 5 on the OLED layer structure, caused by the strict temperature restrictions during coating, is generally inadequate for large-area applications, there is in this case provision for busbar assistance. Accordingly, the busbar grid structure is insulated with respect to the cathode layer 8 on the substrate.

FIG. 6 shows the substrate 1 with the cathode 8 arranged directly on it. The patterned insulator layer 3.2, with the busbar structure 3.1 applied to it, is arranged on the cathode 8. The conductive HTL polymer layer 6 and the light-emitting EL polymer layer (EL) 7 have been at least partially introduced into the depressions 3.3 in the busbar structure. The conductive transparent anode layer 5 has been applied right at the top.

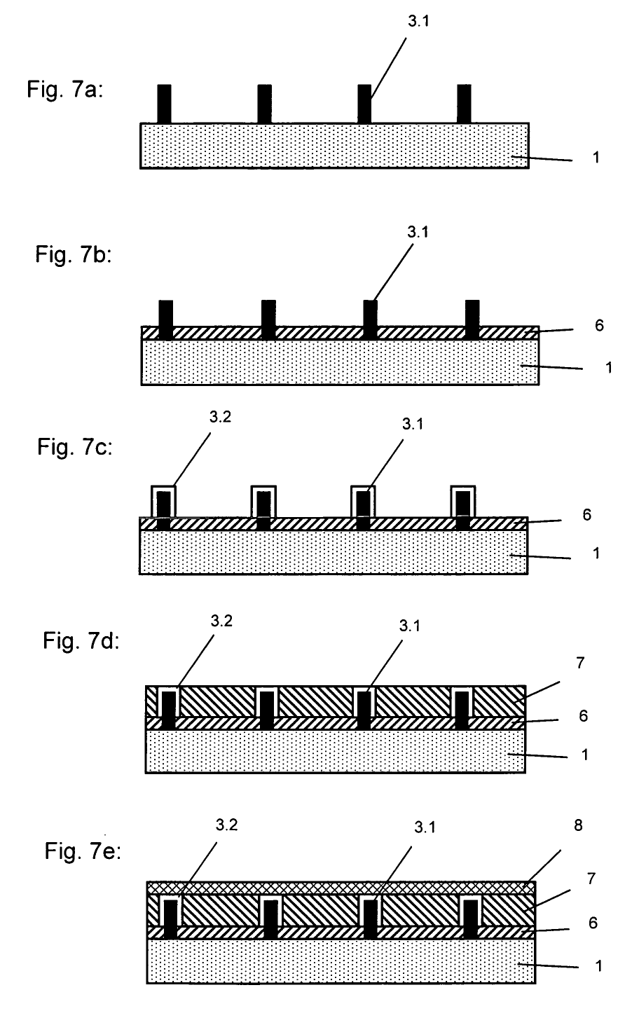

In a further embodiment, it is possible to do without the TCO coating of the substrate. This is because the conductivity of the HTL layer (PEDOT or PANI) is sufficient for local distribution of current over the area if the busbar grid structure is appropriately designed. FIG. 7a to 7e outline the corresponding coating steps involved in the inkjet coating of the active “recess structure” of the busbar grid without a TCO layer.

The layers are applied to the substrate 1 in the following order:

FIG. 7a: busbar 3.1 for delimiting the structure and distributing current,

FIG. 7b: conductive HTL polymer layer 6,

FIG. 7c: insulator layer 3.2,

FIG. 7d: light-emitting EL polymer layer 7, and

FIG. 7e: cathode 8.

In accordance with the exemplary embodiment shown in FIG. 7a to 7e, first of all the busbars 3.1 are applied to the substrate and are in direct contact with the conductive transparent layer 6 (e.g. PEDOT) within the recesses, which is then produced by inkjet technology or other suitable liquid coating processes. To avoid short circuits, the busbars are then insulated by means of the insulator layer 3.2, and the remaining OLED layer sequence 7, 8 is applied.

In this context, there are no critical temperature restrictions in the busbar deposition. It is also possible first of all to apply the conductive transparent HTL layer over the entire surface using suitable liquid coating processes, e.g. dip coating techniques, spin coating, etc., and then to form the insulated busbar structure above it by coating in a similar way to that shown in FIG. 3.

In addition to inkjet processes, other liquid coating processes, such as for example screen printing or blade coating, may also be positively influenced by a busbar grid structure during layer formation or with a view to achieving the required uniformity.

The busbar structure which is generally required for large-area illumination applications to increase the surface conductivities is in this case used for two functions. However, this also links different demands on the grid system, such as
distribution of the current density (resulting from the uniformity of the application of light)
width of and distance between the busbar lines (mean surface conductance and minimum transparency of the coating)
height and surface condition of the busbars (filling and wetting properties of the recesses)
geometry and size of the mesh openings (filling properties).

As far as possible uniformly distributed, ideally identically shaped recess structures in a fixably preset pattern are used for the inkjet process.

Furthermore, it is preferable to introduce identical volumes of liquid or the same number of droplets at predetermined intervals, in particular by means of automatic control.

In a rectangular grid pattern, it is preferable for the structure to be moved over sequentially by the inkjet printing head or a predetermined series of nozzles to increase the printing rate, in particular for pixelated display applications.

The demands imposed with regard to the uniform current distributions, in particular in the case of components which are not rectangular, however, lead to locally different formations of the busbar grid. As a compromise between these contradictory requirements, the grid structure should as far as possible be designed as a rectangular or honeycomb grid, and local conductivity fluctuations should be achieved by varying the web widths.

The present process becomes particularly attractive if it is possible to make do without complex and expensive lithography steps during production of the busbar grid structure, and instead use is made of simple printing processes, such as screen printing, offset printing, roll printing or electrophotographic processes, e.g. computer-to-glass (CTG). These processes could then also be used to apply the insulation and/or passivation of the busbar surface to avoid short circuits.

Sumary of the Advantages of the Process

Use of material-saving liquid coating processes for applying the solution to unpatterned, uniform large substrate surfaces
Homogenization of the layer properties by locally delimited deposition
Subsequent expensive cleaning and patterning steps for the polymer coating (for example uncovering of the contact or encapsulation surfaces by laser ablation) are eliminated
The busbar structure which is generally required for large-area illumination applications in order to increase the surface conductivities in this case performs two functions.
The use of inexpensive and/or flexible coating processes (copying and printing techniques) for the busbar structure is possible, since OLED luminous applications do not impose high demands on lateral resolutions and accuracies compared to display applications
Substrate pretreatments immediately before the application of solvent (increasing the wetting properties) and possible ways of influencing the layer formation (subsequent polymerization, partial or complete crosslinking) using a very wide range of methods can additionally be integrated in the process.
Application can also be extended to inverted systems, i.e. with the cathode on the substrate and the anode applied to the layer system.
   Preferred Refinements of the Invention
Control of the liquid distribution within the recesses
Optimization of the recess geometry
Control of the atmosphere and/or the solvent content
Pretreatment of the substrate surface
Aftertreatment of the electroluminescent layer or the film
Multiple layer systems are applied with different layers or films by arranging inkjets or similar rows of nozzles in parallel
The polymer or monomer films are crosslinked, in particular within a film or between the films, in particular in a system.
The first layer (6, 7) is applied and/or layers or film partitions are locally crosslinked and/or residual liquid fractions are removed by flushing with solvent or by suction and/or the second layer (6, 7) is applied and locally crosslinked at the free positions or depressions.
   Application Areas (List Not Exhaustive)
Display technology: e.g. backlights for mobile phones, PDAs or LCD displays in general
Advertising: information boards and illuminated boards
Signage: information boards and illuminated boards
Domestic: switch and sensor illumination (cooking hobs), illuminated floors, special lighting
Ambience, design: luminous surfaces
Automotive, avionics: information boards and illuminated boards, switch and sensor illumination
Outdoors: emergency lighting, portable lights, optionally battery-operated

It will be clear to the person skilled in the art that the embodiments described above are to be understood as examples and that the invention is not restricted to these embodiments, but rather can be varied in numerous ways without departing from the scope of the invention.

1. A process for producing an organic light-emitting device, comprising the steps of:
applying a first conductive electrode to a substrate;
producing a surface with depressions on the substrate, the depressions being defined by electrical interconnects; and
introducing an organic light-emitting material in the depressions.

2. The process as claimed in claim 1, wherein producing the surface with depressions comprises applying a patterned layer.

3. The process as claimed in claim 2, wherein the patterned layer is electrically conductive.

4. The process as claimed in claim 2, wherein the patterned layer comprises a layer in grid form.

5. The process as claimed in claim 2, wherein the patterned layer defines busbars.

6. The process as claimed in claim 1, wherein introducing the organic light-emitting material in the depressions comprises applying the organic light-emitting material in a liquid state.

7. The process as claimed in claim 1, wherein introducing the organic light-emitting material in the depressions comprises a process selected from the group consisting: an inkjet process, a blade-coating process, a screen printing process, and any combinations thereof.

8. The process as claimed in claim 2, wherein the patterned layer is brought into electrically conductive contact with the first conductive electrode.

9. The process as claimed in claim 1, wherein the first conductive electrode comprises a transparent conductive layer.

10. The process as claimed in claim 2, wherein the patterned layer is applied between the first conductive electrode and a second conductive electrode.

11. The process as claimed in claim 10, wherein the second conductive electrode comprises a metal layer.

12. The process as claimed in claim 10, further comprising applying the patterned layer and the second conductive electrode so as to be at least directly electrically insulated from one another.

13. The process as claimed in claim 10, further comprising applying an insulator layer between the patterned layer and the second conductive electrode.

14. The process as claimed in claim 1, wherein the organic light-emitting material comprises a polymer.

15. The process as claimed in claim 1, wherein the step of applying the organic light-emitting material comprises applying a light-emitting polymer layer.

16. The process as claimed in claim 1, further comprising applying a conductive polymer layer.

17. A process for producing an organic light-emitting device, comprising:
applying a transparent conductive electrode to a substrate;
applying a conductive patterned layer to produce depressions on the substrate, the depressions being defined by electrical interconnects;
applying a conductive polymer layer in the depressions;
applying a patterned insulator layer to electrically insulate the conductive patterned layer;
applying a light-emitting polymer layer in the depressions; and
applying a cathode layer, the cathode layer being insulated from direct contact with the conductive patterned layer by the patterned insulator layer.

18. A process for producing an organic light-emitting device, comprising:
applying a cathode layer to a substrate;
applying a patterned insulator layer to electrically insulate the cathode layer;
applying a conductive patterned layer comprising depressions defined by electrical interconnects;
applying a light-emitting polymer layer in the depressions;
applying a conductive polymer layer in the depressions; and
applying a transparent conductive electrode over the conductive patterned layer.

19. A light-emitting device comprising:
a substrate;
at least a first electrode;
a patterned layer defining depressions having electrical interconnects;
a light-emitting layer comprising a light-emitting material arranged in the depressions.

20. (canceled)

21. The device as claimed in claim 19, wherein the patterned layer comprises a layer in grid form.

22. (canceled)

23. The device as claimed in claim 19, wherein the light-emitting material is solidified in the depressions.

24. The device as claimed in claim 19, wherein the light-emitting material is applied to the depressions using a process selected from the group consisting of an inkjet process, a blade coating process, a screen printing process, and any combinations thereof.

25. The device as claimed in claim 19, wherein the patterned layer and the first electrode are directly electrically conductively contact-connected to one another.

26. The device as claimed in claim 19, wherein the first electrode comprises a transparent conductive layer.

27. The device as claimed in claim 19, wherein the patterned layer is arranged between the first electrode and a second electrode.

28. The device as claimed in claim 27, wherein the second electrode is a metallic cathode layer.

29. The device as claimed in claim 27, wherein the patterned layer and the second electrode are at least directly electrically insulated from one another.

30. The device as claimed in claim 27, further comprising a patterned insulator layer arranged between the patterned layer and the second electrode.

31. The device as claimed in claim 19, wherein the light-emitting material comprises an organic polymer.

32. The device as claimed in claim 19, further comprising a conductive polymer layer adjacent to the light-emitting layer.

33. The device as claimed in claim 19, further comprising radiation of light being output through the substrate or in the opposite direction to the substrate.
